(19) United States
(12) Patent Application Publication
(10) Pub. No.: US 2012/0119819 A1
(43) Pub. Date: May 17, 2012

(54) CURRENT CIRCUIT HAVING SELECTIVE TEMPERATURE COEFFICIENT

(75) Inventors: Seung Chul PYO, Suwon (KR); Dong Ok HAN, Suwon (KR); Sung Tae KIM, Incheon (KR); Soo Woong LEE, Seoul (KR); Kyung Uk KIM, Seoul (KR); Sang Gyu PARK, Anyang (KR)

(73) Assignee: SAMSUNG ELECTRO-MECHANICS CO., LTD., Gyunggi-do (KR)

(21) Appl. No.: 13/009,618

(22) Filed: Jan. 19, 2011

(30) Foreign Application Priority Data
Nov. 12, 2010 (KR) 10-2010-0112879

(51) Int. Cl. H01L 37/00

(52) U.S. Cl. 327/513

(57) ABSTRACT

There is provided a current circuit having a selective temperature coefficient. The current circuit may include: a first current generating unit generating a first current having a positive temperature characteristic which increases depending on temperature; a second current generating unit generating a second current having a negative temperature characteristic which decreases depending on temperature; a multiplying unit multiplying and outputting each of the first current and the second current; and a switching unit selectively synthesizing and outputting a plurality of currents outputted from the multiplying unit depending on on/off control signals. Therefore, it is possible to prevent performance from being deteriorated by temperature and easily and efficiently adjust a temperature coefficient through a simple switching logic.

### CROSS-REFERENCE TO RELATED APPLICATIONS

This application claims the priority of Korean Patent Application No. 10-2010-0112879 filed on Nov. 12, 2010, in the Korean Intellectual Property Office, the disclosure of which is incorporated herein by reference.

### BACKGROUND OF THE INVENTION

1. Field of the Invention

The present invention relates to a current circuit, and more particularly, to a current circuit having a selective temperature coefficient capable of preventing performance from being deteriorated by temperature and easily and efficiently adjusting a temperature coefficient through a simple switching logic by multiplying a first current having a positive temperature characteristic which increases depending on temperature and a second current having a negative characteristic which decreases depending on temperature and selectively synthesizing and outputting a plurality of multiplied currents.

2. Description of the Related Art

In spite of the low power consumption and temperature characteristics of an operational amplifier in various application fields, supplying a constant current is an important evaluation item of the operation amplifier. In particular, a current circuit capable of compensating a temperature change is required in an IC driven under an environment in which the temperature change is large. Therefore, various types of current sources for temperature compensation which are less influenced by temperature and can provide a constant current have been under consideration in order to satisfy a requirement.

A known temperature compensation circuit uses a mode of making a current unrelated to temperature by merely synthesizing a current source having a positive temperature characteristic which increases depending on temperature and a current source having a negative characteristic which decreases depending on temperature.

However, the known mode is disadvantageous in that it is difficult to easily adjust a temperature coefficient.

### SUMMARY OF THE INVENTION

An aspect of the present invention provides a current circuit having a selective temperature coefficient capable of easily and efficiently adjusting a desired temperature coefficient through a simple switching logic.

According to an aspect of the present invention, there is provided a current circuit including: a first current generating unit generating a first current having a positive temperature characteristic which increases depending on temperature; a second current generating unit generating a second current having a negative temperature characteristic which decreases depending on temperature; a multiplying unit multiplying and outputting each of the first current and the second current; and a switching unit selectively synthesizing and outputting a plurality of currents outputted from the multiplying unit depending on on/off control signals.

Preferably, the current circuit may further include a logic determining unit generating the on/off control signals. In addition, the current circuit may further include a current mirroring unit mirroring the currents outputted from the switching unit.

In addition, the multiplying unit may output at least two multiplied currents with respect to each of the first current and the second current.

Moreover, the first current generating unit and the second current generating unit may include a beta multiplier circuit.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a block diagram of a current circuit having a selective temperature coefficient according to an exemplary embodiment of the present invention;

FIG. 2 is a detailed block diagram of a current circuit having a selective temperature coefficient according to an exemplary embodiment of the present invention;

FIG. 3 is a configuration diagram of a beta multiplier circuit applied to a first current generating unit and a second current generating unit according to an exemplary embodiment of the present invention; and

FIG. 4 is a diagram showing a current waveform synchronized by various switching logics according to an exemplary embodiment of the present invention.

### DETAILED DESCRIPTION OF THE PREFERRED EMBODIMENT

Exemplary embodiments of the present invention will now be described in detail with reference to the accompanying drawings.

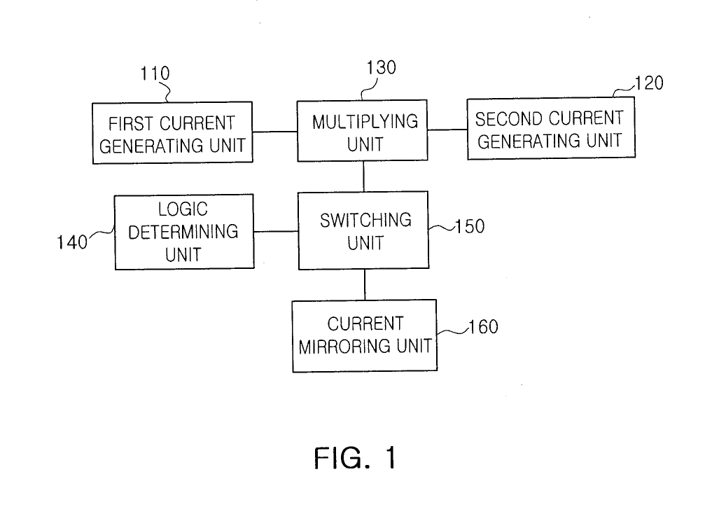

FIG. 1 is a block diagram of a current circuit having a selective temperature coefficient according to an exemplary embodiment of the present invention. The current circuit may include a first current generating unit 110, a second current generating unit 120, a multiplying unit 130, a logic determining unit 140, a switching unit 150, and a current mirroring unit 160.

Referring to FIG. 1, the first current generating unit 110 generates a first current having a proportional temperature to absolute temperature (PTAT), i.e., a positive temperature characteristic which increases depending on temperature. The first current which is generated is outputted to the multiplying unit 130.

Meanwhile, the second current generating unit 120 generates a second current having a complementary temperature to absolute temperature (CTAT), i.e., a negative temperature characteristic which decreases depending on temperature. The second current which is generated is outputted to the multiplying unit 130.

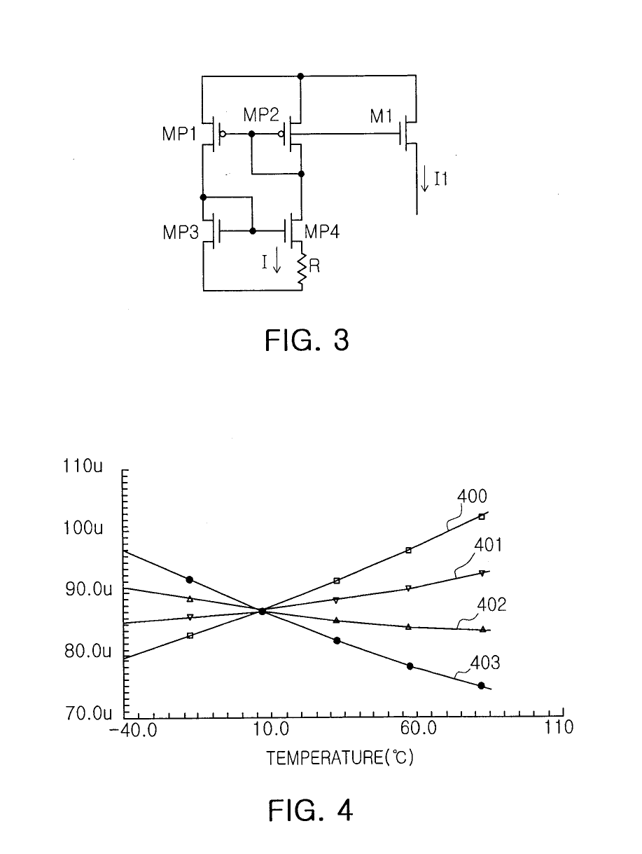

Preferably, the first current generating unit 110 and the second current generating unit 120 may include a beta multiplier circuit. The beta multiplier circuit will be described below with reference to FIG. 3.

Meanwhile, the multiplying unit 130 may include amplifiers mirroring the current having the PTAT component of the first current generating unit 110 and a plurality of amplifiers mirroring the current having the CTAT component of the second current generating unit 120. Herein, the amplifiers may include a metal oxide semiconductor field-effect transistor (MOSFET). The magnitude of a current that flows on each MOSFET of the multiplying unit 130 having such a structure may be adjusted by adjusting a ratio (W/L) of the width and the length of a channel.

In detail, the multiplying unit 130 multiplies each of the first current having the positive temperature characteristic increased depending on temperature, which is received from the first current generating unit 110 and the second current having the negative temperature characteristic decreased depending on temperature. A plurality of currents which are multiplied are outputted to the switching unit 150. Preferably, at least two multiplied currents are outputted with respect to the first current and the second current outputted from the first current generating unit 110 and the second current generating unit 120, respectively.

Meanwhile, the logic determining unit 140 generates on/off control signals for switching a plurality of switching elements of the switching unit 150 such that the current circuit has a desired temperature coefficient. The generated on/off control signals are outputted to the switching unit 150.

The switching unit 150 turns its internal switching elements on/off depending on the on/off control signals outputted from the logic determining unit 140 to selectively synthesize and output the plurality of currents outputted from the multiplying unit 130. Preferably, the switching element includes the metal oxide semiconductor field-effect transistor (MOSFET).

The current mirroring unit 160 includes a plurality of mirroring amplifiers and outputs a current acquired by amplifying the synthesized current outputted from the switching unit 150. In this case, the magnitude of the outputted current may be adjusted by adjusting the ratio (W/L) of the width and the length of the channel.

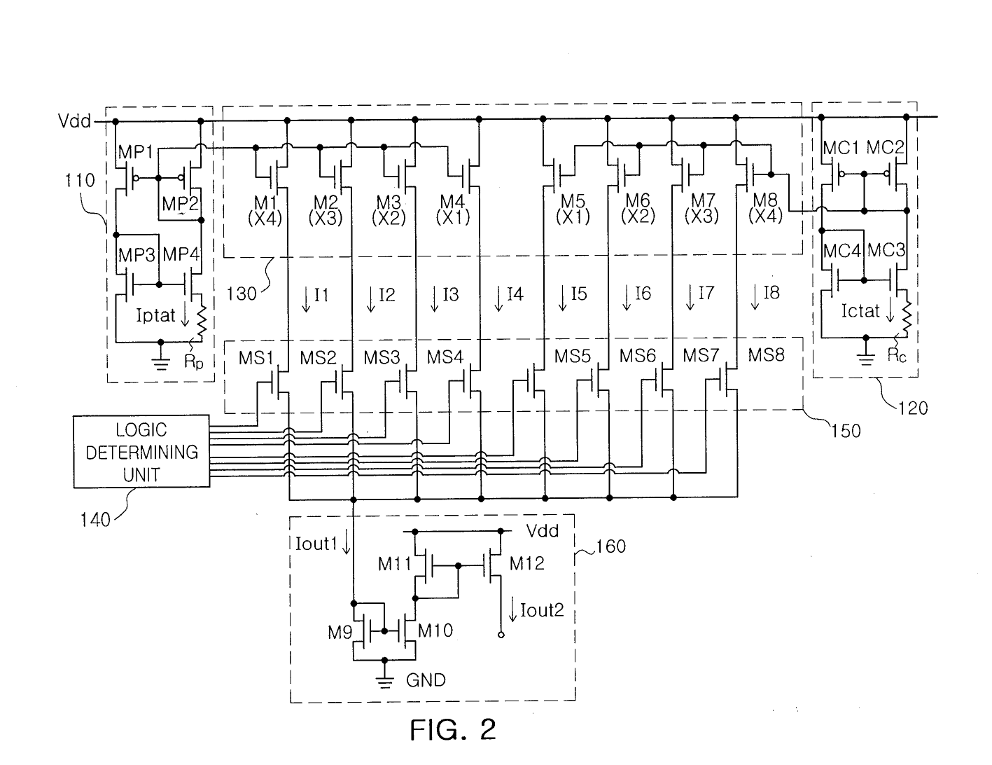

Meanwhile, FIG. 2 is a detailed block diagram of the current circuit according to the exemplary embodiment of the present invention.

Referring to FIG. 2, the first current generating unit 110 and the second current generating unit 120 may include the beta multiplier circuit. A detailed configuration of the beta multiplier circuit will be described below with reference to FIG. 3.

The multiplying unit 130 includes amplifiers M1 to M8 connected to a driving power supply Vdd. In detail, the first amplifier M1 four-time amplifies the first current Iptat having the PTAT component, the second amplifier M2 three-time amplifies the first current Iptat having the PTAT component, the third amplifier M3 twice amplifies the first current Iptat having the PTAT component, and the fourth amplifier M4 once amplifies the first current Iptat having the PTAT component. Similarly, the fifth amplifier M5 once amplifies the second current Ictat having the CTAT component, the sixth amplifier M6 twice amplifies the second current Ictat having the CTAT component, the seventh amplifier M7 three-time amplifies the second current Ictat having the CTAT component, and the eighth amplifier M8 four-time amplifies the second current Ictat having the CTAT component. Herein, the amplifiers may include a metal oxide semiconductor field-effect transistor (MOSFET). The magnitude of a current that flows in each of the MOSFETs M1 to M8 of the multiplying unit 130 having such a structure may be adjusted by adjusting the ratio (W/L) of the width and the length of a channel. As described above, in the present invention, four currents which are multiplied once to four times for each of the first current Iptat and the second current Ictat are exemplified, but it is merely an exemplification and may be modified to various numbers according to the needs of those skilled in the art.

Meanwhile, the switching unit 150 includes the plurality of switching elements MS1 to MS8 which are connected to the amplifiers M1 to M8 of the multiplying unit 130, respectively and turned on/off depending on the on/off control signals from the logic determining unit 140. The switching unit 150 is switched depending on the on/off control signals to selectively sum up and output the currents I1 to I8 outputted from the multiplying unit 130. As such, according to the exemplary embodiment of the present invention, it is possible to prevent performance from being deteriorated by temperature and easily and efficiently adjust a desired temperature coefficient through a simple switching logic by selectively synthesizing and outputting the plurality of currents.

Lastly, the current mirroring unit 160 may include a plurality of mirroring amplifiers M9 to M12 and additionally amplify the synchronized current Iout1 outputted from the switching unit 150 to output a current Iout2. Similarly, the magnitude of the outputted current Iout2 may be adjusted by adjusting the ratio (W/L) of the width and the length of the channel.

FIG. 3 is a configuration diagram of a beta multiplier circuit applied to a first current generating unit 110 and a second current generating unit 120 according to an exemplary embodiment of the present invention.

Referring to FIG. 3, assumed that it is designed that the width of an MP4 is k times larger than that of an MP3 and the length of the MP4 is the same as that of the MP3, an amplification rate is shown in Equation 1.

β2=K×β1 Equation 1

Herein, β2 represents the amplification rate of the MP4 and β1 represents the amplification rate of the MP3.

When a mismatch and a λ effect are disregarded, the current mirrors MP3 and MP4 provide the same current. When KVL is applied, Equation 2 can be acquired.

Vgs1=Vgs2+IR Equation 2

Herein, Vgs1 represents a gate-source voltage of the MP3 and Vgs2 represents a gate-source voltage of the MP4. When a body effect, a channel-length modulation, and a mobility modulation are disregarded and Vgs is substituted, Equation 3 can be acquired.

$$( \sqrt{\frac{2 I}{{β}_{1}}} + {V}_{THN} ) = ( \sqrt{\frac{2 I}{{β}_{2}}} + {V}_{THN} ) + IR \\ ( \sqrt{\frac{2 I}{{β}_{1}}} + {V}_{THN} ) = ( \sqrt{\frac{2 I}{K \cdot {β}_{1}}} + {V}_{THN} ) + IR \qquad Equation 3$$

Thereafter, when Equation 3 is solved with respect to I, Equation 4 can be acquired.

$$I = \frac{2}{{R}^{2} {β}_{1}} \cdot {( 1 - \sqrt{\frac{1}{K}} )}^{2} \qquad Equation 4$$

Referring to Equation 4, a current may be expressed as a coefficient which is in inverse proportion to the square of a resistance value R. A characteristic of the beta multiplier circuit may be determined depending on a characteristic of the resistance R. In detail, a resistance R of the first current generating unit 110 is set as a resistance Rp having a positive temperature coefficient as shown in FIG. 1, such that the first current generating unit 110 may have the PTAT characteristic. Similarly, a resistance R of the second current generating unit 120 is set as a resistance Rc having a negative temperature coefficient as shown in FIG. 1, such that the second current generating unit 120 may have the CTAT characteristic. The beta multiplier circuit is merely an exemplary embodiment and may be implemented as various types of current sources.

FIG. 4 is a diagram showing a current waveform synchronized by various switching logics according to an exemplary embodiment of the present invention.

Hereinafter, an operational principle of the present invention will be described with reference to FIGS. 1 to 4.

Referring to FIGS. 1 to 4, the first current generating unit 110 generates the first current Iptat having the positive temperature characteristic which increases depending on temperature and outputs it to the multiplying unit 130 and similarly, the second current generating unit 120 generates the second current Ictat having the negative temperature characteristic which decreases depending on temperature and outputs it to the multiplying unit 130.

The multiplying unit 130 mirrors and amplifies the first current Iptat from the first current generating unit 110 and the second current Ictat from the second current generating unit 120. In detail, the first amplifier M1 four-time amplifies the first current Iptat having the PTAT component, the second amplifier M2 three-time amplifies the first current Iptat having the PTAT component, the third amplifier M3 twice amplifies the first current Iptat having the PTAT component, and the fourth amplifier M4 once amplifies the first current Iptat having the PTAT component. Similarly, the fifth amplifier M5 once amplifies the second current Ictat having the CTAT component, the sixth amplifier M6 twice amplifies the second current Ictat having the CTAT component, the seventh amplifier M7 three-time amplifies the second current Ictat having the CTAT component, and the eighth amplifier M8 four-time amplifies the second current Ictat having the CTAT component. Meanwhile, the magnitude of a current that flows on each of the MOSFETs (M1 to M8) of the multiplying unit 130 having such a structure may be adjusted by adjusting the ratio (W/L) of the width and the length of a channel.

Thereafter, the switching unit 150 turns its internal switching elements MS1 to MS8 on/off depending on the on/off control signals outputted from the logic determining unit 140 to selectively synthesize and output the plurality of currents I1 to I8 outputted from the multiplying unit 130.

A waveform of the sum-up current outputted from the switching unit 150 is shown in FIG. 4.

Referring to FIGS. 1 and 4, reference numeral 400 represents an output current Iout1 acquired by four-time multiplying the first current Iptat, once multiplying the second current Ictat, and summing up the multiplied currents. For this, the logic determining unit 140 may output the on/off control signals to turn on the switching elements MS1 and MS5 and turn off the rest of the switching elements MS2 to MS4 and MS6 to MS8 to the switching unit 150. Similarly, reference numeral 401 represents an output current Iout1 acquired by three-time multiplying the first current Iptat, twice multiplying the second current Ictat, and summing up the multiplied currents. For this, the logic determining unit 140 may output the on/off control signals to turn on the switching elements MS2 and MS6 and turn off the rest switching elements SM1, MS3 to MS5, and MS7 to MS8 to the switching unit 150. Meanwhile, reference numeral 402 represents an output current Iout1, acquired by twice multiplying the first current Iptat, three-time multiplying the second current Ictat, and summing up the multiplied currents and reference numeral 403 represents an output current Iout1, acquired by once multiplying the first current Iptat, four-time multiplying the second current Ictat, and summing up the multiplied currents. The on/off control signals of reference numerals 402 and 403 may be outputted by the same principle. Components of a limited number of the multiplying unit 130 and the switching unit 150 are shown, but are not limited thereto and various numbers of amplifiers and switching elements may be used. As described above, according to the exemplary embodiment of the present invention, it is possible to prevent performance from being deteriorated by temperature and easily and efficiently adjust a desired temperature coefficient through a simple switching logic by selectively synthesizing and outputting the plurality of currents.

Lastly, the current Iout1 outputted from the switching unit 150 may be additionally amplified through the current mirroring unit 160 and the amplified current Iout2 may be outputted from the current mirroring unit 160.

As set forth above, it is possible to prevent performance from being deteriorated by temperature and easily and efficiently adjust a temperature coefficient through a simple switching logic by multiplying a first current having a positive temperature characteristic which increases depending on temperature and a second current having a negative characteristic which decreases depending on temperature and selectively synthesizing and outputting a plurality of multiplied currents.

While the present invention has been shown and described in connection with the exemplary embodiments, it will be apparent to those skilled in the art that modifications and variations can be made without departing from the spirit and scope of the invention as defined by the appended claims. Accordingly, the scope of the present invention will be determined by the appended claims.

What is claimed is:

1. A current circuit having a selective temperature coefficient, comprising:
a first current generating unit generating a first current having a positive temperature characteristic which increases depending on temperature;
a second current generating unit generating a second current having a negative temperature characteristic which decreases depending on temperature;
a multiplying unit multiplying and outputting each of the first current and the second current; and
a switching unit selectively synthesizing and outputting a plurality of currents outputted from the multiplying unit depending on on/off control signals.

2. The current circuit of claim 1, further comprising a logic determining unit generating the on/off control signals.

3. The current circuit of claim 2, further comprising a current mirroring unit mirroring the currents outputted from the switching unit.

4. The current circuit of claim 3, wherein the multiplying unit outputs at least two multiplied currents with respect to each of the first current and the second current.

5. The current circuit of claim 4, wherein the first current generating unit and the second current generating unit include a beta multiplier circuit.
